(19) United States
(12) Patent Application Publication
(10) Pub. No.: US 2026/0068437 A1
(43) Pub. Date: Mar. 5, 2026

(54) CAPACITOR STRUCTURES AND METHODS FOR MANUFACTURING THE SAME

(71) Applicant: Taiwan Semiconductor Manufacturing Co., Ltd., Hsinchu (TW)

(72) Inventors: Jheng-Hong JIANG, Hsinchu (TW); Shing-Huang WU, Hshinchu (TW)

(21) Appl. No.: 18/821,621

(22) Filed: Aug. 30, 2024

(51) Int. Cl. H10K 59/121; H10K 59/12

(52) U.S. Cl. CPC H10K 59/1216; H10K 59/1201

(57) ABSTRACT

A trench capacitor structure including a lower conductive layer, a lower non-conductive layer stacked on the lower conductive layer, an intermediate conductive layer on the lower conductive layer, an upper non-conductive layer on the intermediate conductive layer, and an upper conductive layer on the upper non-conductive layer. The lower conductive layer including a first U-shaped portion, the intermediate conductive layer including a second U-shaped portion within the first U-shaped portion, and the upper conductive layer includes a pillar portion that is within the second U-shaped portion. A first capacitance is present between the lower conductive layer and the intermediate conductive layer, and a second capacitance is present between the upper conductive layer and the intermediate conductive layer.

### BACKGROUND

Pixels are utilized within electronic devices to display images on a display screen. For example, in an OLED (Organic Light-Emitting Diode) layer of an electronic device, a plurality of pixels are present within the OLED layer. Each respective pixel of the plurality of pixels includes a plurality of sub-pixels. The plurality of sub-pixels generally includes three sub-pixels being an R (red) sub-pixel, a G (green) sub-pixel, and a B (blue) sub-pixel. In other words, each respective pixel of the plurality of pixels includes three sub-pixels such that each respective pixel of the plurality of pixels may be referred to as an RGB pixel. As electronic devices become smaller in profile (e.g., small in overall size and thinner in overall thickness) while improving or increasing in a number of complex functions that are performed, providing a high enough capacitance for the sub-pixels of each respective pixel of the plurality of pixels becomes ever increasingly difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified diagram of at least two pixels.

FIG. 1B is a cross-sectional view of one or more capacitor structures taken along line 1B-1B of a sub-pixel of one of the at least two pixels as shown in FIG. 1A.

FIG. 2 is a cross-sectional view of one or more alternative capacitor structures taken along line 1B-1B of the sub-pixel of one of the at least two pixels as shown in FIG. 1A.

FIG. 3A is a simplified diagram of at least two pixels, in accordance with some embodiments.

FIG. 3B is a cross-sectional view of one or more capacitor structures taken along line 3B-3B of a sub-pixel of one of the at least two pixels as shown in FIG. 3A, in accordance with some embodiments.

FIG. 3C is a top plan view of the one or more capacitor structures with an OLED (Organic Light-Emitting Diode) layer hidden as shown in FIG. 3B, in accordance with some embodiments.

FIG. 4 is a top plan view of one or more alternative capacitor structures with an OLED (Organic Light-Emitting Diode) layer hidden, in accordance with some embodiments.

FIG. 5 is a top plan view of one or more alternative capacitor structures with an OLED (Organic-Light Emitting Diode) layer hidden, in accordance with some embodiments.

FIG. 6A is a zoomed in view of section 6-6 as shown in FIG. 3C, in accordance with some embodiments.

FIG. 6B is a partial reproduction of FIG. 6A, in accordance with some embodiments.

FIG. 6C is a circuit diagram representative of a capacitor structure as shown in FIGS. 6A and 6B, in accordance with some embodiments.

FIG. 7 is a flowchart of a method of manufacturing the one or more capacitor structures of the sub-pixel of the pixel as shown in FIGS. 3A-3C, in accordance with some embodiments.

FIGS. 8A-8L are cross-sectional views of respective steps of the flowchart as shown in FIG. 7 of the method of manufacturing the one or more capacitor structures of the sub-pixel of the pixel as shown in FIGS. 3A-3C, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

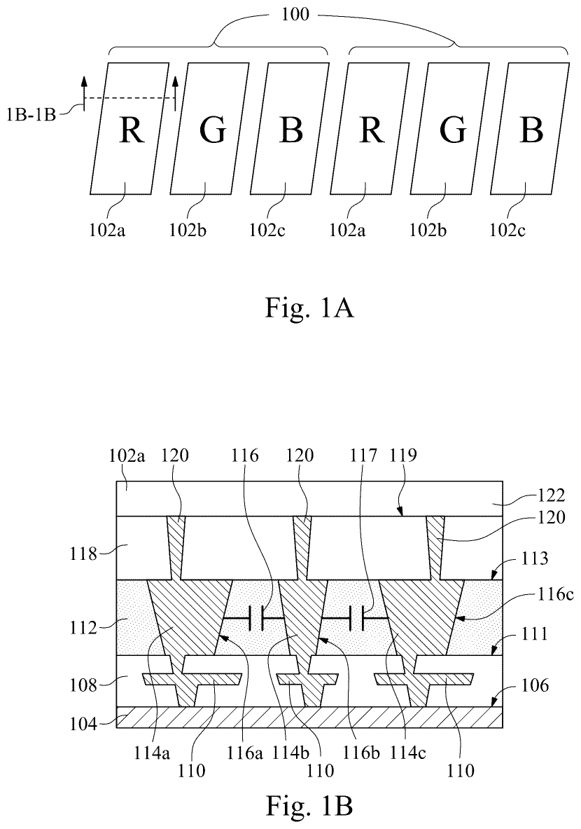

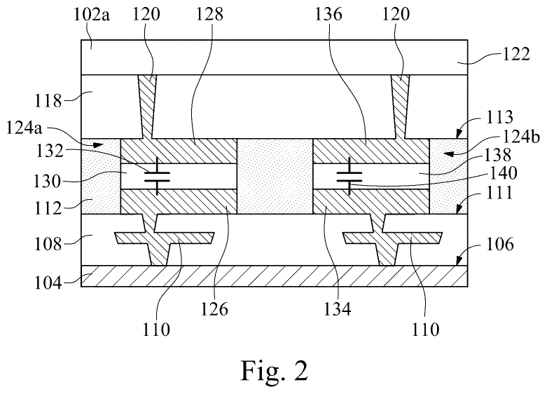

FIG. 1A is a simplified diagram of at least two pixels 100 of a greater pixel array (not shown). Each pixel 100 includes a plurality of sub-pixels 102a, 102b, 102c. In other words, there are three sub-pixels 102a, 102b, 102c for each pixel 100 of the plurality of pixels 100.

FIG. 1B is a cross-sectional view of one or more capacitor structures taken along line 1B-1B of the sub-pixel 102a (left-most sub-pixel as shown in FIG. 1A of the left-most pixel 100 as shown in FIG. 1A). While the following discussion will focus on the left-most sub-pixel 102a as shown in FIG. 1A, it will be readily appreciated that the following discussion will readily apply to the other sub-pixels 102a, 102b, 102c of the pixels 100 as shown in FIG. 1A.

The sub-pixel 102a includes a transistor layer 104, which is a lowermost layer as shown in FIG. 1B. While not shown, the transistor layer 104 includes one or more transistor structures (not shown) and includes a first surface 106. The transistor layer 104 is a front end of line (FEOL) transistor layer. The one or more transistor structures (not shown) are encased within at least one dielectric layer of the transistor layer 104. The dielectric layer of the transistor layer is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

A first dielectric layer 108 is stacked on the first surface 106 of the transistor layer 104. The first dielectric layer 108 is in direct contact with the first surface 106 of the transistor layer 104. The first dielectric layer 108 is made of at least one of the following of an undoped silicate (LK) dielectric material, a carbon doped oxygen rich silicon oxide (ELK) material, a black diamond (BD) material, or some other suitable or like dielectric layer or non-conductive layer.

One or more first interconnect structures 110 are within the first dielectric layer 108. The one or more first interconnect structures 110 extend into and through the first dielectric layer 108 to the first surface 106. The one or more first interconnect structures 110 are coupled to the one or more transistors within the transistor layer 104. The one or more first interconnect structures 110 are exposed and accessible at a second surface 111 of the first dielectric structure 108.

A second dielectric layer 112 is stacked on the second surface 111 of the first dielectric layer 108. The second dielectric layer 112 is in direct contact with the second surface 111 of the first dielectric layer 108. The second dielectric layer 112 includes a third surface 113. The second dielectric layer 112 is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

One or more capacitor structures 114a, 114b, 114c are within the second dielectric layer 112. The one or more capacitor structures 114a, 114b, 114c extend through the second dielectric layer to the one or more first interconnect structures 110 such that each of the one or more capacitor structures 114a, 1146, 114c is coupled to a corresponding first interconnect structure of the one or more first interconnect structures 110. The one or more capacitor structures 114a, 114b, 114c includes a first capacitor structure 114a, a second capacitor structure 114b, and a third capacitor structure 114c. The first capacitor structure 114a and the second capacitor structure 114b define a first capacitance 116, and the second capacitor structure 114b and the third capacitor structure 114c define a second capacitance 117. The first, second, and third capacitor structures 114a, 114b, 114c are exposed from and accessible at the third surface 113 of the second dielectric layer 112. The first capacitor structure 114a includes one or more first sidewalls 116a, the second capacitor structure 114b includes one or more second sidewalls 116b, and the third capacitor structure 114c includes one or more third sidewalls 116c.

A third dielectric layer 118 is stacked on the third surface 113 of the second dielectric layer 112. The third dielectric layer 118 is in direct contact with the third surface 113 of the second dielectric layer 112. The third dielectric layer 118 includes a fourth surface 119. The third dielectric layer is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

One or more second interconnect structures 120 are within the third dielectric layer 118. The one or more second interconnect structures 120 extend into and through the third dielectric layer to the one or more capacitor structures 114a, 114b, 114c. The one or more second interconnect structures 120 are coupled to the one or more capacitor structures 114a, 114b, 114c within the second dielectric layer 112. In other words, each second interconnect structure of the one or more second interconnect structures 120 is coupled to a corresponding capacitor structure of the one or more capacitor structure 114a, 114b, 114c. The one or more second interconnect structures 120 are exposed from and accessible at the fourth surface 119 of the third dielectric layer 118.

A light emitting device layer 122, which may be an OLED (Organic Light-Emitting Diode) layer, is stacked on the fourth surface 119 of the third dielectric layer 118. The light emitting device layer 122 includes one or more light emitting devices (i.e., the one or more pixels 100) that are arranged in an array. The one or more pixels 100 present within the light emitting device layer 122 are utilized to output an image on a display of an electronic device (e.g., a smart phone, a smart tablet, a monitor, a laptop display, or some other similar or like type of electronic device with a display). The sub-pixels 102a, 102b, 102c and the pixels 100 are coupled to the one or more second interconnect structures 120. The OLEDs (not shown) are present within the light emitting device layer 122. The OLEDS (not shown) may be within a dielectric material of the light emitting device layer 122. The dielectric material of the light emitting device layer 122 may be at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

To increase the resolution or the stability of the current to the display to output a more precise and refined image, the one or more first, second, and third sidewalls 116a, 116b, 116c must be increased in size (e.g., increased in height and width) to increase the first and second capacitances 116, 117, respectively. However, the size of the one or more first, second, and third sidewalls 116a, 116b, 116c is limited in the size that it can be increased to due to a critical dimension (CD), which is defined by an amount of space that is readily available within an electronic device. In other words, when the electronic device is small or thin, the one or more first, second, and third sidewalls 116a, 116b, 116c can only be made so large due to the available space that is available to accommodate this increase in size. In other words, the first and second capacitances 116, 117 are limited by the critical dimension that limits the size of the one or more first, second, and third sidewalls 116a, 116b, 116c of the first, second, and third capacitor structures 114a, 114b, 114c.

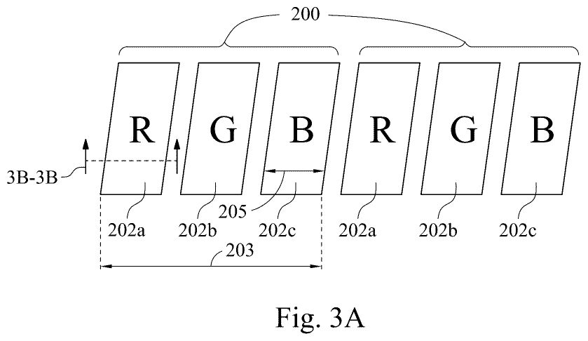

FIG. 2 is a cross-sectional view of one or more capacitor structures taken along line 1B-1B of the sub-pixel 102a (left-most sub-pixel as shown in FIG. 1A of the left-most pixel 100 as shown in FIG. 1A). While the following discussion will focus on the left-most sub-pixel 102a as shown in FIG. 1A, it will be readily appreciated the following discussion will readily apply to the other sub-pixels 102a, 102b, 120c of the pixels 100 as shown in FIG. 1A. The features as shown in FIG. 2 that are the same or similar to the features as shown in FIG. 1A. For the sake of simplicity and brevity of the present disclosure, the details of these same or similar features of FIG. 2 relative to FIG. 1A may not be reproduced in their entirety as follows herein. Instead, the focus of the following discussion with respect to FIG. 2 will be on the additional or different features relative to FIG. 1A.

Unlike the one or more capacitor structures 114a, 114b, 114c, these structures are replaced with one or more capacitor structures 124a, 124b as shown in FIG. 2. The one or more capacitor structures 124a, 124b include a pair of capacitor structures 124a, 124b having a first capacitor structure 124a and a second capacitor structure 124b.

The first capacitor structure 124a includes a first portion 126 at or in close proximity to the second surface 111 of the first dielectric layer 108 and a second portion 128 at or in close proximity to the third surface 113 of the second dielectric layer 112. An intermediate dielectric layer 130 is present between and sandwiched between the first portion 126 and the second portion 128. A first capacitance 132 is present between the first portion 126 and the second portion 128 when an electrical signal is applied to the first capacitor structure 124a. The intermediate dielectric layer 130 may be a high K (HK) dielectric material.

The second capacitor structure 124b includes a first portion 134 at or in close proximity to the second surface 111 of the first dielectric layer 108 and a second portion 136 at or in close proximity to the third surface 113 of the second dielectric layer 112. An intermediate dielectric layer 138 is present between and sandwiched between the first portion 134 and the second portion 136. A second capacitance 140 is present between the first portion 134 and the second portion 136 when an electrical signal is applied to the second capacitor structure 124b.

The first and second capacitance 132, 140 is controlled or adjusted by applying an electrical signal to the first and second capacitors 124a, 124b. However, in order to generate a high or large capacitance a large electrical signal must be applied to the first and second capacitors 124a, 124b. Some of the power requirements to generate the high or large capacitance can be alleviated by increasing the size of the first and second capacitors 124a, 124b, but similar to increasing the size of the first, second, and third capacitor structures 114a, 114b, 114c, the first and second capacitors 124a, 124b can only be made so large before being limited by the critical dimension. In other words, when the electronic device is small or thin, the first and second capacitors 116, 117 can only be made so large due to the available space that is available to accommodate this increase in size. In other words, the first and second capacitances 116, 117 are limited by the critical dimension that limits the size of the one or more first, second, and third sidewalls 116a, 116b, 116c of the first, second, and third capacitor structures 114a, 114b, 114c.

As follows herein, the present disclosure is directed to providing and manufacturing one or more embodiments of one or more capacitor structures for one or more sub-pixels of one or more pixels that prevent or avoid the issues as discussed earlier herein with respect to FIGS. 1A, 1B, 2A, and 2B, respectively. In the semiconductor industry, as displays are manufactured with higher and higher resolutions, capacitors with higher and higher capacitances are desired to provide displays with higher resolutions. Generally, providing capacitors with higher capacitances takes up a greater amount of space. However, the embodiments of the one or more capacitor structures for the one or more sub-pixels of the one or more pixels allows for a large number of capacitors with a high capacitance to be provided within each sub-pixel of one or more pixels. Generally, each pixel incudes three sub-pixels (e.g., an R (red) sub-pixel, a G (green) sub-pixel, and a B (blue) sub-pixel) and each one of these sub-pixels includes one or more capacitor structures that are utilized to allow the one or more pixels to display an image on a display of an electronic system or device (e.g., a smart phone, a smart tablet, a monitor, a laptop display, or some other similar or like type of display).

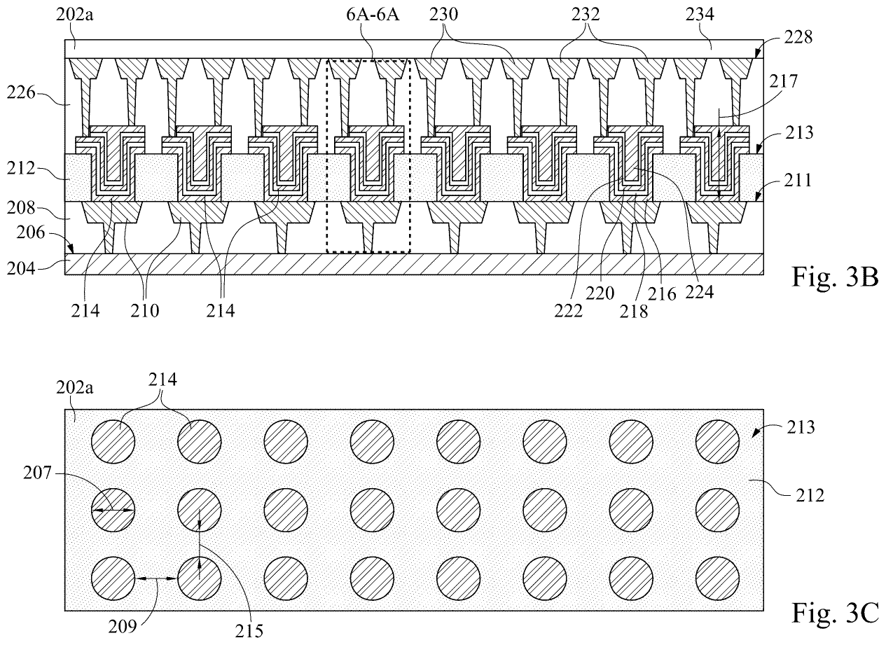

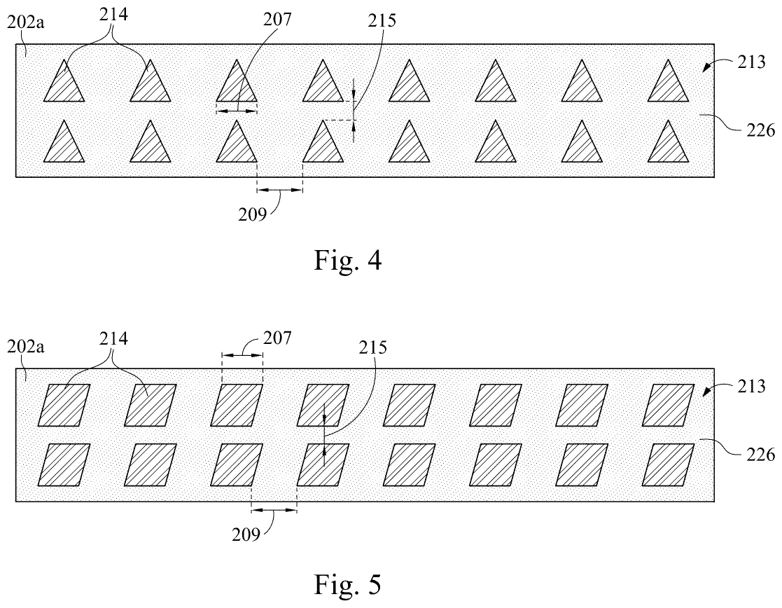

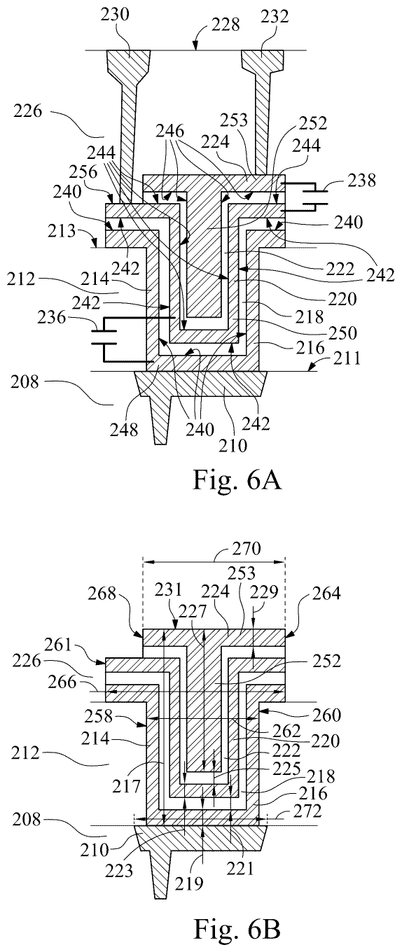

FIG. 3A is a simplified diagram of at least two pixels 200 of a greater pixel array (not shown). Each pixel 200 includes a plurality of sub-pixels 202a, 202b, 202c, in accordance with some embodiments. In other words, there are three sub-pixels 202a, 202b, 202c for each pixel 200 of the plurality of pixels 200. Each pixel 200 has a pixel pitch dimension 203 that extends across the entirety of the sub-pixels 202a, 202b, 202c of the corresponding pixel 200. In this embodiment, the pixel pitch dimension 203 is equal to 60 micrometers (μm).

Each sub-pixel 202a, 202b, 202c has a sub-pixel pitch dimension 205 that is a third of the pixel pitch dimension 203 as there are three sub-pixels 202a, 202b, 202c for each pixel 200 in this embodiment. In this embodiment, the sub-pixel pitch dimension is equal to 20 micrometers (μm).

In some embodiments, the pixel pitch dimension 203 is selected from a range ranging from 2 nanometers (nm) to 1000 micrometers (μm), or is equal to the upper and lower ends of this range. The sub-pixel pitch dimension 205 is selected from a range ranging from 2 nanometers (nm) to 1000 micrometers (μm), or is equal to the upper and lower ends of this range.

FIG. 3B is a cross-sectional view of one or more capacitor structures taken along line 3B-3B as shown in FIG. 3A of the sub-pixel 202a (left-most sub-pixel as shown in FIG. 3A of the left-most pixel 200 as shown in FIG. 3A), in accordance with some embodiments. While the following discussion will focus on the left-most sub-pixel 202a as shown in FIG. 3A, it will be readily appreciated the following discussion will readily apply to the other sub-pixels 202a, 202b, 202c of the pixels 200 as shown in FIG. 3A.

The sub-pixel 202a includes a transistor layer 204, which is a lowermost layer as shown in FIG. 3B. While not shown, the transistor layer 204 includes one or more transistor structures (not shown) and includes a first surface 206. The transistor layer 204 is a front end of line (FEOL) transistor layer. The one or more transistor structures (not shown) are encased within at least one dielectric layer of the transistor layer 204. The dielectric layer of the transistor layer is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

A first dielectric layer 208 is stacked on the first surface 206 of the transistor layer 204. The first dielectric layer 208 is in direct contact with the first surface 206 of the transistor layer 204. The first dielectric layer 208 is made of at least one of the following of an undoped silicate (LK) dielectric material, a carbon doped oxygen rich silicon oxide (ELK) material, a black diamond (BD) material, or some other suitable or like dielectric layer or non-conductive layer.

One or more first interconnect structures 210 are within the first dielectric layer 208. The one or more first interconnect structures 210 extend into and through the first dielectric layer 208 to the first surface 206. The one or more first interconnect structures 210 are coupled to the one or more transistors within the transistor layer 204. The one or more first interconnect structures 210 are exposed and accessible at a second surface 211 of the first dielectric structure 208.

A second dielectric layer 212 is stacked on the second surface 211 of the first dielectric layer 208. The second dielectric layer 212 is in direct contact with the second surface 211 of the first dielectric layer 208. The second dielectric layer 212 includes a third surface 213. The second dielectric layer 212 is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

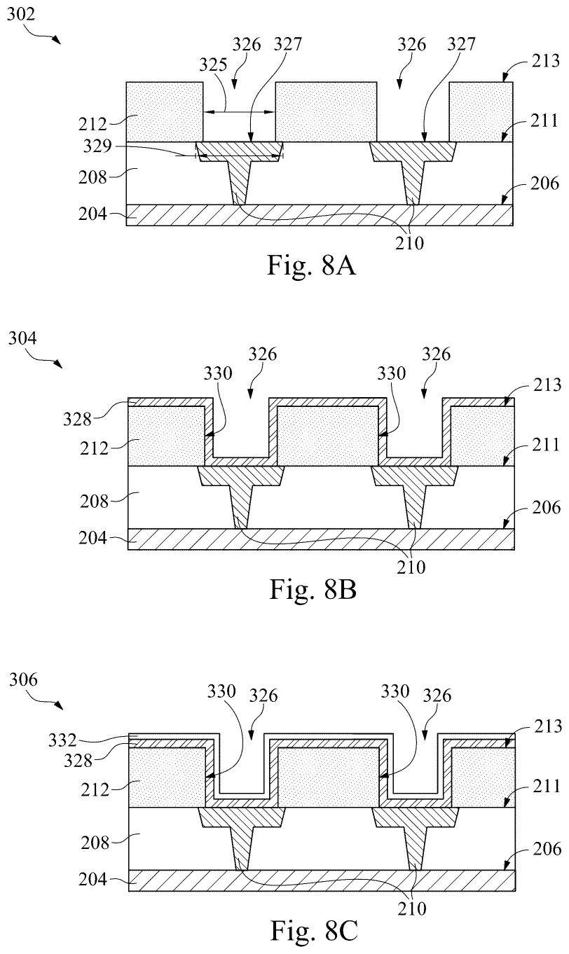

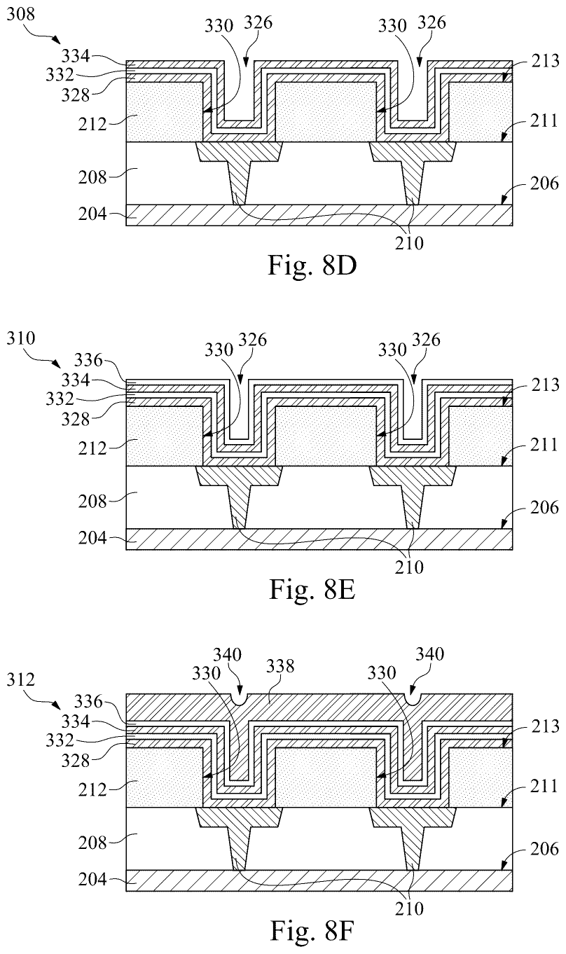

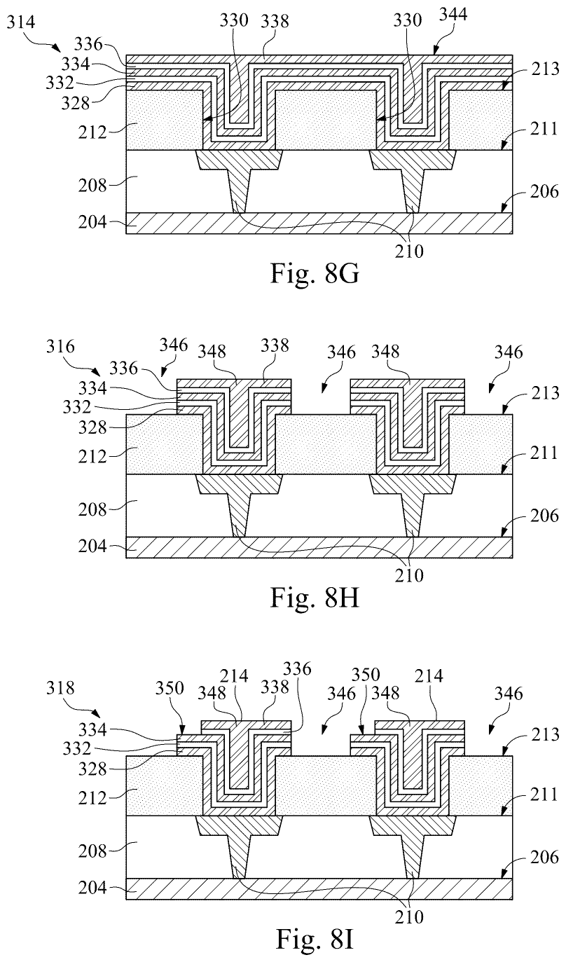

One or more capacitor structures 214 are within the second dielectric layer 212. The one or more capacitor structures 214 extend through the second dielectric layer 212 such that each of the one or more capacitor structures 214 is coupled to a corresponding first interconnect structure of the first interconnect structures 210. As shown in FIG. 3B, the one or more capacitor structures 214 includes eight capacitor structures. In other alternative embodiments, a number of one or more capacitor structures 214 is greater than eight capacitor structures or is less than eight capacitor structures depending on a resolution or functionality of the one or more pixels 200. Each respective capacitor structure of the one or more capacitor structures 214 includes a lower conductive layer 216, a lower non-conductive or dielectric layer 218 that is on the lower conductive layer 216, an intermediate conductive layer 220 that is on the lower non-conductive or dielectric layer 218, an upper non-conductive or dielectric layer 222 that is on the intermediate conductive layer 220, and an upper conductive layer 224 that is on the upper non-conductive or dielectric layer 222. The lower conductive layers 216 of the one or more capacitor structures 214 are in direct contact with and coupled to the one or more first interconnect structures 210. The one or more capacitor structures 214 are on and protrude outward from the third surface 213 of the second dielectric layer 212. The details of these layers and their relationships with each other will be discussed in greater detail with respect to FIG. 6 as follows herein.

A third dielectric layer 226 is stacked on the third surface 213 of the second dielectric layer 212. The third dielectric layer 226 is in direct contact with the third surface 213 of the second dielectric layer 212. The third dielectric layer 226 includes a fourth surface 228. The third dielectric layer 226 is on the one or more capacitor structures 214 that are on and protrude outward from the third surface 213 of the second dielectric layer 212. The third dielectric layer 226 is made of at least one of the following of an undoped silicate glass (USG) material, a silicon nitride (SiN) material, a fluorosilicate glass (FSG) material, a low K (LK) dielectric material, a carbon doped oxygen rich silicon oxide (ELK) material, a black diamond (BD) material, or some other suitable or like dielectric layer or non-conductive layer.

The one or more capacitor structures 214 have a dimension 217 that extends from corresponding surfaces of the first interconnect structures 210 to respective uppermost surfaces of the one or more capacitor structures 214. In at least some embodiments, the dimension 217 is selected from a range from 5 nanometers (nm) to 50 micrometers (μm), or is equal to the upper and lower ends of this range.

One or more second interconnect structures 230 and one or more third interconnect structures 232 are within the third dielectric layer 226. The one or more second interconnect structures 230 and the one or more third interconnect structures 232 extend into and through the third dielectric layer 226 to the one or more capacitor structures 214. The one or more second interconnect structures 230 are slightly longer that the one or more third interconnect structures 232. The one or more second interconnect structures 230 and the one or more third interconnect structures 232 are coupled to the one or more capacitor structures 214 within the second dielectric layer 212 and within the third dielectric layer 226. In other words, each second interconnect structure of the one or more second interconnect structures 230 is coupled to a corresponding capacitor structure of the one or more capacitor structure 214, and each third interconnect structure of the one or more third interconnect structures 232 is coupled to a corresponding capacitor structure of the one or more capacitor structures 214. The one or more second interconnect structures 230 and the one or more third interconnect structures 232 are exposed from and accessible at the fourth surface 228 of the third dielectric layer 226.

A light emitting device layer 234, which may be OLED (Organic Light-Emitting Diode) layer, is stacked on the fourth surface 228 of the third dielectric layer 226. The light emitting device layer 234 includes one or more light emitting devices (i.e., the one or more pixels 200) that are arranged in an array. The one or more pixels 200 present within the light emitting device layer 234 are utilized to output an image on a display of an electronic device (e.g., a smart phone, a smart tablet, a monitor, a laptop display, or some other similar or like type of electronic device with a display). The sub-pixels 202a, 202b, 202c and the pixels 200 are coupled to the one or more second interconnect structures 230 and the one or more third interconnect structures 232.

FIG. 3C is a top plan view of the one or more capacitor structures 214 with the OLED (Organic Light-Emitting Diode) layer 234, the third dielectric layer 226, the one or more second interconnect structures 230, and the one or more third interconnect structures 232 hidden as shown in FIG. 3B, in accordance with some embodiments. In the embodiment as shown in FIG. 3C, the one or more capacitor structures 214 have a cylindrical profile such that upper ends of the one or more capacitor structures 214 have a circular profile. Each capacitor structure of the one or more capacitor structures 214 has a dimension 207. Each capacitor structure of the one or more capacitor structures 214 is spaced apart from an adjacent respective capacitor structure by a dimension 209 in the X-direction based on the orientation as shown in FIG. 3C. Each capacitor structure of the one or more capacitor structures 214 is spaced apart from an adjacent respective capacitor structure by a dimension 215

In this embodiment of the one or more capacitor structures 214 as shown in FIG. 3C, the dimension 207 is equal to 200 nanometers (nm). In this embodiment of the one or more capacitor structures 214, the dimension 209 is equal to 200 nanometers (nm). In this embodiment of the one or more capacitor structures 214, the dimension 209 is equal to 200 nanometers (nm).

In at least some embodiments, the dimension 207 is selected from a range from 2 nanometers (nm) to 70 micrometers (μm), or is equal to the upper and lower ends of this range. In at least some embodiments, the dimension 209 is selected from a range from 2 nanometers (nm) to 70 micrometers (μm), or is equal to the upper and lower ends of this range. In at least some embodiments, the dimension 215 is selected from a range from 2 nanometers (nm) to 70 micrometers (μm), or is equal to the upper and lower ends of this range.

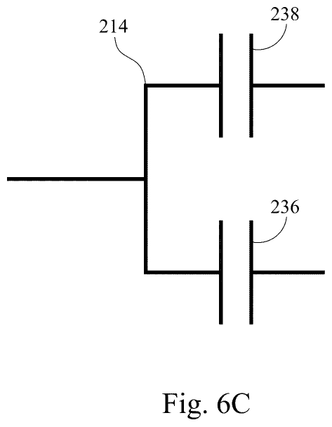

FIG. 4 is a top plan view of the one or more capacitor structures 214 with the OLED (Organic Light-Emitting Diode) layer 234, the third dielectric layer 226, the one or more second interconnect structures 230, and the one or more third interconnect structures 232 hidden as shown in FIG. 4, in accordance with some embodiments. In the embodiment as shown in FIG. 4, the one or more capacitor structures 214 have a triangular prism profile such that upper ends of the one or more capacitor structures 214 have a triangular profile.

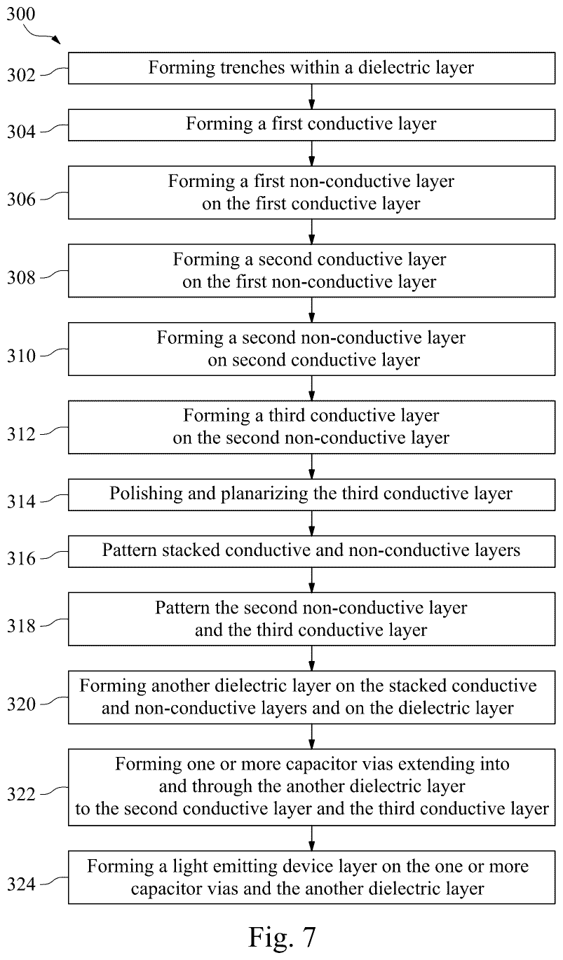

FIG. 5 is a top plan view of the one or more capacitor structures 214 with the OLED (Organic Light-Emitting Diode) layer 234, the third dielectric layer 226, the one or more second interconnect structures 230, and the one or more third interconnect structures 232 hidden as shown in FIG. 5, in accordance with some embodiments. In the embodiment as shown in FIG. 5, the one or more capacitor structures 214 have a trapezoidal prism profile such that upper ends of the one or more capacitor structures 214 have a trapezoidal profile.

FIG. 6A is a zoomed in view of section 6A-6A as shown in FIG. 3B, in accordance with some embodiments. In other words, FIG. 6 is a zoomed in view of one of the one or more capacitor structures 214 as shown in FIG. 3B. In the embodiment as shown in FIG. 6A, a first capacitance 236 is present between the lower conductive layer 216 and the intermediate conductive layer 220 across the lower non-conductive layer 218, and a second capacitance 238 is present between the upper conductive layer 224 and the intermediate conductive layer 220 across the upper non-conductive layer 222. A total capacitance of the capacitor structure 214 as shown in FIG. 6A is a summation of the first capacitance 236 and the second capacitance 238 as the first and second capacitances are in parallel with each other (see, i.e., a circuit diagram for the capacitor structure 214 as shown in FIG. 6C).

The lower conductive layer 216 includes one or more first wall surfaces 240, the intermediate conductive layer 220 includes a one or more second wall surfaces 242 and one or more third wall surfaces 244, and the upper conductive layer 224 includes one or more fourth wall surfaces 246. The one or more second wall surfaces 242 are opposite to the one or more third wall surfaces 244. The first capacitance 236 is present between the one or more first wall surfaces 240 and the one or more second wall surfaces 242, and the second capacitance 238 is present between the one or more third wall surfaces 244 and the one or more fourth wall surfaces 246.

The lower conductive layer 216 includes a first U-shaped portion 248 that delimits a first recess, the intermediate conductive layer 220 includes a second U-shaped portion 250 that delimits a second recess, and the upper conductive layer 224 includes a pillar portion 252 such that the upper conductive layer 224 has a T-shape profile. The second U-shaped portion 250 is present within the first recess defined by the first U-shaped portion 248. The pillar portion 252 is present within the second recess defined by the second U-shaped portion 250. The first recess defined by the first U-shaped portion 248 is delimited by respective first wall surfaces of the one or more first wall surfaces 240. The second recess defined by the second U-shaped portion 250 is delimited by respective third wall surfaces of the one or more third wall surfaces 244.

The upper conductive layer 224 including the pillar portion 252 further includes a peripheral portion 253 that extends outward from the pillar portion 252. The peripheral portion 253 is less thick than the pillar portion 252.

The second interconnect structure 230 as shown in FIG. 6A is coupled to an exposed region 256 of the intermediate conductive layer 220. The exposed region 256 is exposed from the upper non-conductive layer 222 and the upper conductive layer 224. In other words, the upper non-conductive layer 222 and the upper conductive layer 224 are not present on the exposed region 256 of the intermediate conductive layer 220. The third interconnect structure 232 as shown in FIG. 6A is coupled to the upper conductive layer 224.

Unlike the one or more capacitor structures 114a, 114b, 114c as shown in FIG. 1B and the one or more capacitor structures 124a, 124b as shown in FIG. 2 that are limited in their overall and total capacitance due to the critical dimension (CD) issue as discussed earlier herein, the one or more capacitor structures 214 have a higher overall and total capacitance relative to these respective one or more capacitor structures 114a, 114b, 114c. Also, a greater number of the one or more capacitor structures 214 is readily provided in the same amount of space as the one or more capacitor structures 114a, 114b, 114c as shown in FIG. 1B and the one or more capacitor structures 124a, 124b as shown in FIG. 2. The one or more capacitor structures 214 have a higher overall or total capacitance relative to the one or more capacitor structures 114a, 114b, 114c, 124a, 124b in the same or lesser amount of space due to the first U-shaped portion 248 of the lower conductive layer 216, the second U-shaped portion 250 of the intermediate conductive layer 220, and the pillar portion 252 of the upper conductive layer 224. The first U-shaped portion 248, the second U-shaped portion 250, and the pillar portion 252 allow for the one or more first wall surfaces 240, the one or more second wall surfaces 242, the one or more third wall surfaces 244, and the one or more fourth wall surfaces 246 to be maximized in size such that the first capacitance 236 and the second capacitance 238 is higher than the first capacitances 116, 132 and the second capacitances 117, 140, respectively.

The first U-shaped portion 248, the second U-shaped portion 250, and the pillar portion 252 allow for the one or more capacitor structures 214 to be smaller than the one or more capacitor structures 114a, 114b, 114c, 124a, 124b such that a greater number of the one or more capacitor structures 214 is capable of being provided in the same amount of space as the one or more capacitor structures 114a, 114b, 114c, 124a, 124b. For example, since the sub-pixel 202a has the sub-pixel pitch dimension 205 that is equal to 20 micrometers (μm) and the dimension 207 for each capacitor structure of the one or more capacitor structures 214 is equal to 200 nanometers (nm), a total number of capacitor structures 214 that are capable of being provided within the sub-pixel 202a is equal to one hundred, which is a larger number than a total number of capacitors when instead utilizing the one or more capacitor structures 114a, 114b, 114c, 124a, 124b as shown in FIGS. 1B and 2. As the one or more capacitor structures 214 have a higher capacitance and a greater number of them are capable of being provided within each sub-pixel 202a, 202b, 202c of each pixel 200, the one or more capacitor structures 214 allow for an electronic device to have a display with greater stability and better resolution when instead the one or more capacitor structures 114a, 114b, 114c, 124a, 124b are utilized. In other words and to summarize, the one or more capacitors structures 214 provide a higher capacitance while at the same time a greater number is capable of being provided within the same amount of space relative to the one or more capacitor structures 114a, 114b, 114c, 124a, 124b as shown in FIGS. 1B and 2. By having a higher capacitance and being able to provide a greater number of the one or more capacitor structures 214 in the sub-pixel 202a relative to the one or more capacitor structures 114a, 114b, 114c, 124a, 124b, the one or more capacitor structures 214 are capable of being utilized in a display to provide greater stability and functionality.

The first capacitance 236 ranges from 0.005 pico-Farad (pf) to 100 Farad (F). The second capacitance 238 ranges from 0.005 pico-Farad (pf) to 100 Farad (F). The total capacitance of the capacitor structures is equal to a summation of the first capacitance 236 and the second capacitance 238. In some embodiments, the total capacitance ranges from 0.01 pico-Farad (pF) to 200. Farad (F), or is equal to the upper and lower ends of this range.

The first interconnect structures 210, the second interconnect structures 230, and the third interconnect structures 232 may be made of at least one of the following of a copper material, a copper alloy material, a tungsten material, a tungsten alloy material, or some other similar or like type of conductive material. The lower conductive material 216, the intermediate conductive layer 220, and the upper conductive layer 224 may be made of at least one of the following of a copper material, a copper alloy material, a tungsten material, a tungsten alloy material, or some other similar or like type of conductive material. The lower non-conductive layer 218 and the upper non-conductive layer 222 may be made of a high K (HK) dielectric material selected from at least one of the following of SiO₂, SiNₓ, HfSiO₄, ZrO₂, HfO₂, TiO₂, or some other similar or like type of high K (HK) dielectric material.

FIG. 6B is a partial reproduction of FIG. 6A to provide further details with respect to dimensions of the capacitor structure 214 as shown in FIG. 6A. In other words, only the capacitor structure 214 and the first interconnect structure 210 have been reproduced in FIG. 6B relative to FIG. 6A, and the second interconnect structure 230 and the third interconnect structure 232 are not reproduced in FIG. 6B.

A first dimension 219, which is a thickness of the lower conductive layer 216, extends from a respective surface of the first interconnect structure 210 to a respective first wall surface of the one or more first wall surfaces 240. In at least this embodiment, the first dimension 219 is within a range from 0.5 nanometers to 50 micrometers (μm), or is equal to the upper and lower ends of this range.

A second dimension 221, which is a thickness of the lower non-conductive layer 218, extends from the first conductive layer 216 to the intermediate conductive layer 220. In at least this embodiment, the second dimension is within a range from 0.5 nanometers (nm) to 50 micrometers (μm), or is equal to the upper and lower ends of this range.

A third dimension 223, which is a thickness of the intermediate conductive layer 220, extends from the lower non-conductive layer 218 to the upper non-conductive layer 222. In at least this embodiment, the third dimension is within a range form 0.5 nanometers (nm) to 50 micrometers (μm), or is equal to the upper and lower ends of this range.

A fourth dimension 225, which is a thickness of the upper non-conductive layer 222, extends from the intermediate conductive layer 220 to the upper conductive layer 224. In at least this embodiment, the fourth dimension 225 is within a range from 0.5 nanometers (nm) to 50 micrometers (μm), or is equal to the upper and lower ends of this range.

A fifth dimension 227, which is a thickness of the pillar portion 252 of the upper conductive layer 224, extends from an end of the pillar portion 252 to a respective upper surface of the upper conductive layer 224. The respective upper surface of the upper conductive layer 224 231 faces away from the first interconnect structure 210. In at least this embodiment, the fifth dimension 227 is within a range from 2.5 nanometers (nm) to 250 micrometers (μm), or is equal to the upper and lower ends of this range.

A sixth dimension 229, which is a thickness of the upper conductive layer 224, extends from the upper non-conductive layer 222 to the respective upper surface 231 of the upper conductive layer 224. The sixth dimension 229 is less than the fifth dimension 227. In at least this embodiment, the sixth dimension 229 is within a range from 0.5 nanometers (nm) to 50 micrometers (μm), or is equal to the upper and lower ends of this range.

The pillar portion 252 of the upper conductive layer 224 of the capacitor structure 214 has the fifth dimension 227. The peripheral portion 253 of the upper conductive layer 224 of the capacitor structure 214 has the sixth dimension 229.

The capacitor structure 214 as shown in FIG. 6B further includes a first side 258 and a second side 260 opposite to the first side 258. A first width 262 extends form the first side 258 to the second side 260. The first width 262 is within a range from 2 nanometers (nm) to 500 micrometers (μm), or is equal to the upper and lower ends of this range.

The capacitor structure 214 as shown in FIG. 6B further includes a third side 261 and a fourth side 264 opposite to the third side 261. The third side 261 is spaced outward from the first side 258, and the fourth side 264 is spaced outward from the second side 260. A second width 266 extends from the third side 252 to the fourth side 264. The second width 266 is greater than the first width 262. The second width 266 is within a range from 2 nanometers (nm) to 500 micrometers (μm), or is equal to the upper and lower ends of this range.

The capacitor structure 214 as shown in FIG. 6B further includes a fifth side 268 is spaced inward from the third side 261. A third width 270 extends from the fifth side 268 to the fourth side 264. The third width 270 is less than the second width 266. The third width 270 is within a range from 2 nanometers (nm) to 500 micrometers (μm), or is equal to the upper and lower ends of this range.

A fourth width 272 extends from opposing sides or ends of the first interconnection structure 210 as shown in FIG. 6B. The fourth width 272 is greater than the first width 262 and is less than the second width 226. The fourth width 272 is within a range from 2 nanometers (nm) to 500 micrometers (μm), or is equal to the upper and lower ends of this range.

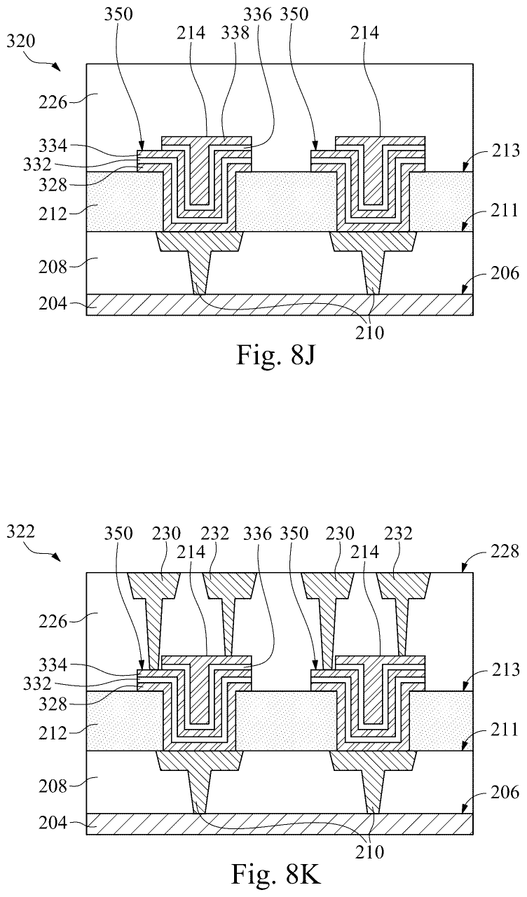

FIG. 7 is a flowchart 300 of a method of manufacturing the one or more capacitor structures 214 of the sub-pixel 202a of the pixel 200 as shown in FIGS. 3A-3C, in accordance with some embodiments. The flowchart 300 includes a plurality of steps including a first, second, third, fourth, fifth, sixth, seventh, eighth, ninth, tenth, eleventh and twelfth step 302, 304, 306, 308, 310, 312, 314, 316, 318, 320, 322, 324.

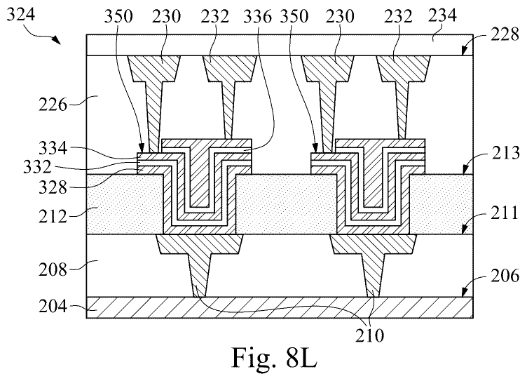

FIGS. 8A-8L are cross-sectional views of respective steps of the flowchart 300 as shown in FIG. 7 of the method of manufacturing the one or more capacitor structures 214 of the sub-pixel 202a of the pixel 200 as shown in FIGS. 3A-3C, in accordance with some embodiments. The details of the respective steps 302, 304, 306, 308, 310, 312, 314, 316, 318, 320, 322, 324 will be discussed in conjunction with the details as illustrated in FIGS. 8A-8L. As will be readily appreciated, features that are the same or similar to those features as shown in FIGS. 3A-3C will be provided with the same or similar reference numerals as shown in FIGS. 8A-8L. Furthermore, for the sake of simplicity and brevity of the present disclosure, the details of these features that were already described with respect to FIGS. 3A-3C may not be described in detail again as follows herein.

In the first step 302 as shown in FIG. 8A, one or more trenches 326 are formed extending into the third surface 213 of the second dielectric layer 212. The one or more trenches 326 expose respective surfaces of the one or more first interconnect structures 210. In other words, there is generally a one-to-one relationship with respect to the one or more first interconnect structures 210 and the one or more trenches 326.

The one or more trenches 326 are formed by some technique known to the semiconductor industry to form the one or more trenches 326 within the second dielectric layer 212. For example, in at least one embodiment, the one or more trenches 326 are formed by dry etching respective regions of the second dielectric layer 212. The one or more regions of the second dielectric layer 212 are exposed to a photoresist patterning process. For example, after forming a photoresist material around the one or more regions along the third surface 213 of the second dielectric layer 212, the one or more regions are then exposed to a dry etching process in which a chemical etchant is applied to the one or more regions of the second dielectric layer 212 resulting in removal of respective portions of the second dielectric layer 212 forming the one or more trenches 326 exposing the respective surfaces of the one or more first interconnect structures 210 from the second dielectric layer 212. Once the dry etching has occurred and been completed, the photoresist material is removed from the third surface 213 of the second dielectric layer 212 resulting in a structure or assembly as shown in FIG. 8A. As shown in FIG. 8A, a width 325 of each respective trench of the one or more trenches 326 is less than a second width 329 of respective surfaces 327 of each respective first interconnect structure the one or more first interconnect structures 210. In at least this embodiment, the width 325 is within a range from 2 nanometers (nm) to 20 micrometers (μm), or is equal to the upper and lower ends of this range. In at least this embodiment, the second width 329 is within a range from 2 nanometers (nm) to 20 micrometers (μm), or is equal to the upper and lower ends of this range. In other words, the second width 329 is the same as the fourth width 272 as discussed earlier herein.

In at least one embodiment, the width 325 is equal to the first width 262 as shown in FIG. 6B. In at least one embodiment, the width 329 is equal to the second width 266 as shown in FIG. 6B.

After the one or more trenches 326 are formed in the first step 302, in the second step 304 as shown in FIG. 8B, a first conductive layer 328 is formed on the third surface 213 of the second dielectric layer 212, is formed on one or more sidewalls 330 of the second dielectric layer 212 that delimit the one or more trenches 326, and the respective surfaces of the one or more first interconnect structures 210 exposed by forming the one or more trenches 326. The first conductive layer 328 corresponds to the lower conductive layer 216 of the capacitor structure 214 as shown in FIG. 6A. The first conductive layer 328 is formed by a deposition technique known to the semiconductor industry. For example, the first conductive layer 328 is formed by physical vapor deposition process (PVD) in which the first conductive layer 328 is formed thinly along the third surface 213, the one or more sidewalls 330, and the respective surfaces of the one or more first interconnect structures 210.

After the first conductive layer 328 is formed in the second step 304, in a third step 306 as shown in FIG. 8C, a first non-conductive layer 332 is formed on the first conductive layer 328. The first non-conductive layer 332 is formed to cover all of the first conductive layer 328. The first non-conductive layer 332 corresponds to the lower non-conductive layer 218 as shown in FIG. 6A. The first non-conductive layer 332 is formed by a deposition technique known to the semiconductor industry. For example, in at least one embodiments, the first non-conductive layer 332 is formed by an atomic layer deposition process (ALD) such that the first non-conductive layer 332 is formed thinly across the entirety and fully along respective surfaces and sidewalls of the first conductive layer 328.

After the third step 306 in which the first non-conductive layer 332 is formed on the first conductive layer 328, in the fourth step 308 as shown in FIG. 8D, a second conductive layer 334 is formed on the first non-conductive layer 332. The second conductive layer 334 is formed to cover all of the first non-conductive layer 332. The second conductive layer 334 corresponds to the intermediate conductive layer 220 as shown in FIG. 6A. The second conductive layer 334 is formed by a deposition technique known to the semiconductor industry. For example, in at least one embodiment, the second conductive layer 334 is formed by a physical vapor deposition process (PVD) in which the second conductive layer 334 is formed thinly across the entirety and fully along respective surfaces and sidewalls of the first non-conductive layer 332.

After the fourth step 308 in which the second conductive layer 334 is formed on the first non-conductive layer 332, in a fifth step 310 as shown in FIG. 8E, a second non-conductive layer 336 is formed on the second conductive layer 334. The second non-conductive layer 336 corresponds to the upper non-conductive layer 222 of the capacitor structure 214 as shown in FIG. 6A. The second non-conductive layer 336 is formed by a deposition technique known to the semiconductor industry. For example, in at least one embodiment, the second non-conductive layer 336 is formed by an atomic layer deposition process (ALD) in which the second non-conductive layer 336 is formed thinly across the entirety and fully along respective surfaces and sidewalls of the second conductive layer 334.

After the fifth step 310 in which the second non-conductive layer 336 is formed, in the sixth step 312 as shown in FIG. 8F, a third conductive layer 338 is formed on the second non-conductive layer 336. The third conductive layer 338 corresponds to the upper conductive layer 224 of the capacitor structure 214 as shown in FIG. 6A. The third conductive layer 338 is formed by a deposition technique known to the semiconductor industry. For example, in at least one embodiment, the third conductive layer 338 is formed by a physical vapor deposition process (PVD) in which the third conductive layer 338 is formed thinly across the entirety and fully along respective surfaces and sidewalls of the second non-conductive layer 336. As shown in FIG. 8F, after the third conductive layer 338 has been formed, the one or more trenches 326 have been fully and completely filled by the first conductive layer 328, the first non-conductive layer 332, the second conductive layer 334, the second non-conductive layer 336, and the third conductive layer 338. After the third conductive layer 338 has been formed, one or more notches 340 are present within the third conductive layer 338 and are aligned with the one or more trenches 326 that were previously unfilled. The one or more notches 340 are formed as the third conductive layer 338 fills a remaining portion of the one or more trenches 326 not previously filled by the first conductive layer 328, the first non-conductive layer 332, the second conductive layer 334, and the second non-conductive layer 336.

After the sixth step 312 in which the third conductive layer 338 is formed, in a seventh step 314 as shown in FIG. 8G, the third conductive layer 338 is polished and planarized forming an upper surface 344 of the third conductive layer 338. The third conductive layer 338 is polished or planarized with a technique known to the semiconductor industry. For example, in at least one embodiment, the third conductive layer 338 is polished or planarized with a chemical mechanical polishing (CMP) process in which the third conductive layer 338 is polished and planarized forming the upper surface 344. By forming the upper surface 344 of the third conductive layer 338 with the CMP process, the one or more notches 340 are removed as enough of the third conductive layer 338 is polished away resulting in the upper surface 344 being level and flat.

After the seventh step 314 in which the third conductive layer 338 is polished and planarized refining and forming the upper surface 344 of the third conductive layer 338, in the eighth step 316 as shown in FIG. 8H, the first conductive layer 328, the first non-conductive layer 332, the second conductive layer 334, the second non-conductive layer 336, and the third conductive layer 338 are patterned resulting in removing portions of the first conductive layer 328, the first non-conductive layer 332, the second conductive layer 334, the second non-conductive layer 336, and the third conductive layer 338. Removing these respective portions of the first conductive layer 328, the first non-conductive layer 332, the second conductive layer 334, the second non-conductive layer 336, and the third conductive layer 338 results in forming recesses 346 around and adjacent to the one or more stacked structures 348. The one or more stacked structures 348 are a partial formation of the one or more capacitor structures 214 as discussed in detail earlier herein. The one or more recesses 346 are formed to define the one or more stacked structures 348 with one or more formation processes known within the semiconductor industry. For example, in at least one embodiment, the recesses 346 are formed by forming a photoresist material on one or more regions of the upper surface 344 of the third conductive layer 338 that correspond the one or more stacked structure 348 that are to be formed. Once the photoresist material is formed at the one or more regions of the upper surface 344 corresponding to the one or more stacked structures 348, the first conductive layer 328, the first non-conductive layer 332, the second conductive layer 334, the second non-conductive layer 336, and the third conductive layer 338 are exposed to a chemical etchant (e.g., during a dry etching process) resulting in the removal of the first conductive layer 328, the first non-conductive layer 332, the second conductive layer 334, the second non-conductive layer 336, and the third conductive layer 338 forming the one or more recesses 346 and defining the one or more stacked structures 348. As shown in FIG. 8H, the one or more stacked structures 348 have a T-shape.

After the eighth step 316 in which the one or more recesses 346 and the one or more stacked structures 348 are formed, in a ninth step 318 as shown in FIG. 8I, one or more regions 350 of the second conductive layer 334 are exposed from the second non-conductive layer 336 and the third conductive layer 338. The one or more regions 350 correspond to the exposed region 256 as of the capacitor structure 214 as shown in FIG. 6A. The one or more regions 350 are formed utilizing one or more process techniques known to the semiconductor industry. For example, in at least one embodiment, the one or more regions 350 are formed by applying a photoresist material to one or more regions along upper surfaces of the third conductive layers 338 of the one or more stacked structures 348 while leaving respective regions of the third conductive layers 338 corresponding to the one or more regions 350 to be formed remaining exposed. The photoresist material is also formed on the third surface 213 of the second dielectric layer 212. The respective regions of the third conductive layer 338 and the second non-conductive layer 336 are exposed to a chemical etchant (e.g., during a dry etching process) removing the respective portions of the third conductive layer 338 and the second non-conductive layer 336 at the respective regions forming the one or more regions 350 of the second conductive layers 334 that are exposed from the third conductive layers 338 and the second non-conductive layers 336 of the stacked structures 348. Forming the one or more regions 350 of the second conductive layer 334 results in the one or more stacked structures 348 now being the one or more capacitor structures 214 fully formed and completed (e.g., FIG. 6A of the present disclosure). Once the one or more regions 350 of the second conductive layer 334 have been exposed from the third conductive layers 338 and the second non-conductive layers 336 of the stacked structures 348, the photoresist material is removed resulting in the structure or assembly as shown in FIG. 8I.

After the ninth step 318 in which the one or more stacked structures 348 are now the one or more capacitor structures 214, in a tenth step 320 as shown in FIG. 8J, the third dielectric layer 226 is formed on the third surface 213 of the second dielectric layer 212 and on the one or more stacked structures 348. The third dielectric layer is formed by a deposition technique known to the semiconductor industry. For example, in at least one embodiment, the third dielectric layer 226 is formed by a physical vapor deposition (PVD) process in which the third dielectric layer 226 is formed to fully cover the one or more stacked structures 348 and the third surface 213 of the second dielectric layer 212.

After the tenth step 320 in which the third dielectric layer 226 is formed on the third surface 213 of the second dielectric layer 212 and on the one or more stacked structures 348, in the eleventh step 322 as shown in FIG. 8K, the one or more second interconnect structures 230 and the one or more third interconnect structures 232 are formed extending into and through the third dielectric layer 226 to the one or more stacked structures 348 (i.e., the one or more capacitor structures 214). The one or more second and third interconnect structures 230, 232 are formed by one or more process techniques known to the semiconductor industry. For example, in at least one embodiment, the one or more second and third interconnect structures 230, 232 are formed by performing one or more etching and conductive formation techniques successively to form the one or more second and third interconnect structures 230, 232. The one or more second interconnect structures 230 are coupled to the one or more regions 250 of the second conductive layers 334 of the one or more stacked structures 348, and the one or more third interconnect structures 232 are coupled to the third conductive layers 338 of the one or more stacked structures 348.

After the eleventh step 322 in which the second and third interconnect structures 230, 232 are formed, in the twelfth step 324 as shown in FIG. 8L, the light emitting device layer 234 is formed on the one or more second interconnect structures 230, the one or more third interconnect structures 232, and the fourth surface 228 of the third dielectric layer 226. The light emitting device layer 234 is formed by performing one or more process and formation techniques and steps to form the one or more sub-pixels 202a, 202b, 202c of the pixel 200 of the pixel array on the one or more second interconnect structures 230, the one or more third interconnect structures 232, and the fourth surface 228 of the third dielectric layer 226.

As discussed earlier herein in detail, unlike the one or more capacitor structures 114a, 114b, 114c as shown in FIG. 1B and the one or more capacitor structures 124a, 124b as shown in FIG. 2 that are limited in their overall and total capacitance due to the critical dimension (CD) issue as discussed earlier herein, the one or more capacitor structures 214 have a higher overall and total capacitance relative to the respective one or more capacitor structures 114a, 114b, 114c. Also, a greater number of the one or more capacitor structures 214 is readily provided in the same amount of space as the one or more capacitor structures 114a, 114b, 114c as shown in FIG. 1B and the one or more capacitor structures 124a, 124b as shown in FIG. 2. The one or more capacitor structures 214 have a higher overall or total capacitance relative to the one or more capacitor structures 114a, 114b, 114c, 124a, 124b in the same or lesser amount of space due to the first U-shaped portion 248 of the lower conductive layer 216, the second U-shaped portion 250 of the intermediate conductive layer 220, and the pillar portion 252 of the upper conductive layer 224. The first U-shaped portion 248, the second U-shaped portion 250, and the pillar portion 252 allow for the one or more first wall surfaces 240, the one or more second wall surfaces 242, the one or more third wall surfaces 244, and the one or more fourth wall surfaces 246 to be maximized in size such that the first capacitance 236 and the second capacitance 238 is higher than the first capacitances 116, 132 and the second capacitances 117, 140, respectively.

The first U-shaped portion 248, the second U-shaped portion 250, and the pillar portion 252 allow for the one or more capacitor structures 214 to be smaller than the one or more capacitor structures 114a, 114b, 114c, 124a, 124b such that a greater number of the one or more capacitor structures 214 is capable of being provided in the same amount of space as the one or more capacitor structures 114a, 114b, 114c, 124a, 124b. For example, since the sub-pixel 202a has the sub-pixel pitch dimension 205 that is equal to 20 micrometers (μm) and the dimension 207 for each capacitor structure of the one or more capacitor structures 214 is equal to 200 nanometers (nm), a total number of capacitor structures 214 that are capable of being provided within the sub-pixel 202a is equal to one hundred, which is a larger number than a total number of capacitors when instead utilizing the one or more capacitor structures 114a, 114b, 114c, 124a, 124b as shown in FIGS. 1B and 2. As the one or more capacitor structures 214 have a higher capacitance and a greater number of them is capable of being provided within each sub-pixel 202a, 202b, 202c of each pixel 200, the one or more capacitor structures 214 allow for an electronic device to have a display with greater stability and better resolution when instead the one or more capacitor structures 114a, 114b, 114c, 124a, 124b are utilized. In other words and to summarize, the one or more capacitors structures 214 provide a higher capacitance while at the same time a greater number is capable of being provided within the same amount of space relative to the one or more capacitor structures 114a, 114b, 114c, 124a, 124b as shown in FIGS. 1B and 2. By having a higher capacitance and being able to provide a greater number of the one or more capacitor structures 214 in the sub-pixel 202a relative to the one or more capacitor structures 114a, 114b, 114c, 124a, 124b, the one or more capacitor structures 214 are capable of being utilized in a display to provide greater stability and functionality.

At least one embodiment of a device of the present disclosure is summarized as including: a transistor layer containing one or more transistors; a first dielectric layer on the transistor layer; a plurality of first interconnection structures that extend into the first dielectric layer to the transistor layer and are coupled to the one or more transistors; a second dielectric layer on the first dielectric layer; a plurality of capacitive connection structures that extend into and through the second dielectric layer to the plurality of first interconnection structures, each respective capacitive connection structure is coupled to a corresponding first interconnection structure of the plurality of first interconnection structures, and each respective capacitive connection structure of the plurality of capacitive connection structures includes: a first conductive layer in contact with and stacked on a respective first interconnection structure of the plurality of first interconnection structures; a third dielectric layer in contact with and stacked on the first conductive layer; a second conductive layer in contact with and stacked on the third dielectric layer; a fourth dielectric layer in contact with and stacked on the second conductive layer; and a third conductive layer in contact with and stacked on the fourth dielectric layer; a fifth dielectric layer on the second dielectric layer and on the plurality of capacitive connection structures; a plurality of second interconnection structures that extend into and through the fifth dielectric layer to the plurality of capacitive connection structures and are coupled to the plurality of capacitive connection structures; and a luminous device layer on the fifth dielectric layer and on the plurality of second interconnection structures.

At least one embodiment of a device of the present disclosure is summarized as including: a transistor layer containing one or more transistors; a first dielectric layer on the transistor layer; a first interconnection structure that extends through the first dielectric layer to the transistor layer; a second dielectric layer on the first dielectric layer; a capacitive connection structure that extends through the second dielectric layer to the first interconnection structure, the capacitive connection structure is in contact with and coupled to the first interconnection structure, the capacitive connection structure including: a first conductive layer in contact with the first interconnection structure; a third dielectric layer on the first conductive layer; a second conductive layer on the third dielectric layer; a fourth dielectric layer on the second conductive layer; and a third conductive layer on the fourth dielectric layer; a fifth dielectric layer on the third conductive layer, and on the second conductive layer; a second interconnection structure that extends through the fifth dielectric layer, the second interconnection structure is in contact with and coupled to the second conductive layer; and a third interconnection structure extends through the fifth dielectric layer, the third interconnection structure is in contact with and coupled to the third conductive layer.

At least one embodiment of a method of the present disclosure is summarized as including: forming a plurality of trenches through a first dielectric layer exposing first surfaces of a plurality of first interconnection structures within a second dielectric layer on which the first dielectric layer is present; forming a first conductive layer on a second surface of the first dielectric layer, in the plurality of trenches, and on the first surfaces of the plurality of first interconnection structures; forming a third dielectric layer on the first conductive layer; forming a second conductive layer on the third dielectric layer; forming a fourth dielectric layer on the second conductive layer; forming a third conductive layer on the fourth dielectric layer; removing first portions of the first conductive layer, the third dielectric layer, the second conductive layer, the fourth dielectric layer, and the third conductive layer defining a plurality of capacitive connection structures; removing second portions of the fourth dielectric layers and the third conductive layers of the plurality of capacitive connection structures to expose regions of the second conductive layers of the plurality of capacitive connection structures; forming a fifth dielectric layer on the first dielectric layer and on the plurality of capacitive connection structures; forming a plurality of second interconnection structures extending into and through the fifth dielectric layer to the regions of the second conductive layers of the plurality of capacitive connection structures, each respective second interconnection structure of the plurality of second interconnection structures being in contact with and coupled to a corresponding exposed region of the exposed regions of the second conductive layers of the plurality of capacitive connection structures; and forming a plurality of third interconnection structures extending into and through the fifth dielectric layer to the third conductive layers of the plurality of capacitive connection structures, each respective third interconnection structure of the plurality of third interconnection structures is coupled to a corresponding third conductive layer of the third conductive layers of the plurality of capacitive connection structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a capacitive connection structure includes:
a first conductive layer;
a first dielectric layer in contact with and stacked on the first conductive layer;
a second conductive layer in contact with and stacked on the first dielectric layer and spaced apart from the first conductive layer by the first dielectric layer;
a second dielectric layer in contact with and stacked on the second conductive layer and spaced apart from the first dielectric layer by the second conductive layer; and
a third conductive layer in contact with and stacked on the second dielectric layer and spaced apart from the second conductive layer by the second dielectric layer, the third conductive layer has a pillar portion having a first thickness and a peripheral portion having a second thickness less than the first thickness.

2. The device of claim 1, further comprising:
a transistor layer containing at least one transistor;
a third dielectric layer on the transistor layer;
a first interconnection structure that extends into the third dielectric layer to the transistor layer and is coupled to the at least one transistor, and the first interconnection structure is coupled to the capacitive connection structure;
a fourth dielectric layer on the third dielectric layer, the fourth dielectric extends around the capacitive connection structure;
a fifth dielectric layer on the fourth dielectric layer and on the capacitive connection structure;
a second interconnection structure that extends into and through the fifth dielectric layer to the capacitive connection structure and is coupled to the capacitive connection structure; and
a luminous device layer on the fifth dielectric layer and on the second interconnect structure, and wherein:
the luminous device layer includes a plurality of pixels, each respective pixel of the plurality of pixels includes at least three sub-pixels.

3. The device of claim 2, wherein:
each pixel of the plurality of pixels has a first pitch selected from a first range of 2 nanometers (nm) to 70 micrometers (μm), inclusive; and
each sub-pixel of the plurality of pixels has a second pitch selected from a second range of 2 nanometers (nm) to 70 micrometers (μm), inclusive.

4. The device of claim 3, wherein the capacitive connection structure has a third pitch less than the second pitch.

5. The device of claim 1, the capacitive connection structure further includes:
a first capacitance is present between the first conductive layer and the second conductive layer across the first dielectric layer; and
a second capacitance is present between the third conductive layer and the second conductive layer across the second dielectric layer.

6. The device of claim 5, wherein a total capacitance of the capacitive connection structure is a summation of the first capacitance and the second capacitance.

7. The device of claim 6, wherein the total capacitance ranges from 0.01 pico-Faradays (pF) to 200 Farads (F), or is equal to the upper and lower ends of this range.

8. The device of claim 1, further comprising an interconnection structure coupled to the capacitive connection structure, and wherein a region of the second conductive layer of the capacitive connection structure is exposed from the second dielectric layer and the third conductive layer of the capacitive connection structure, and the region of the second conductive layer is coupled to the interconnection structure.

9. A device, comprising:
a transistor layer containing one or more transistors;
a first dielectric layer on the transistor layer;
a first interconnection structure that extends through the first dielectric layer to the transistor layer;
a second dielectric layer on the first dielectric layer;
a capacitive connection structure that extends through the second dielectric layer to the first interconnection structure, the capacitive connection structure is in contact with and coupled to the first interconnection structure, the capacitive connection structure including:
a first conductive layer in contact with the first interconnection structure;
a third dielectric layer on the first conductive layer;
a second conductive layer on the third dielectric layer;
a fourth dielectric layer on the second conductive layer; and
a third conductive layer on the fourth dielectric layer;
a fifth dielectric layer on the third conductive layer, and on the second conductive layer;
a second interconnection structure that extends through the fifth dielectric layer, the second interconnection structure is in contact with and coupled to the second conductive layer; and
a third interconnection structure extends through the fifth dielectric layer, the third interconnection structure is in contact with and coupled to the third conductive layer.

10. The device of claim 9, further comprising a luminous device layer on the fifth dielectric layer, on the second interconnection layer, and on the third interconnection structure.

11. The device of claim 10, wherein the luminous device layer is an organic light emitting diode (OLED) layer.

12. The device of claim 9, wherein the capacitive connection structure has a cylindrical profile, a triangular prism profile, a rectangular profile, a square profile, or a trapezoidal profile.

13. The device of claim 9, wherein a region of the second conductive layer is exposed from the fourth dielectric layer and the third conductive layer, and the region of the second conductive layer is in contact with and coupled to the second interconnection structure.

14. The device of claim 9, wherein:
the first interconnection structure includes a first portion and a second portion, the second portion is wider than the first portion, and the second portion is in contact with and coupled to the first conductive layer;
the second interconnection structure includes a third portion and a fourth portion, the fourth portion is wider than the third portion, and the third portion is in contact with and coupled to the second conductive layer; and
the third interconnection structure includes a fifth portion and a sixth portion, the sixth portion is wider than the fifth portion, and the fifth portion is in contact with and coupled to the second conductive layer.

15. A method, comprising:
forming a plurality of trenches through a first dielectric layer exposing first surfaces of a plurality of first interconnection structures within a second dielectric layer on which the first dielectric layer is present;
forming a first conductive layer on a second surface of the first dielectric layer, in the plurality of trenches, and on the first surfaces of the plurality of first interconnection structures;
forming a third dielectric layer on the first conductive layer;
forming a second conductive layer on the third dielectric layer;
forming a fourth dielectric layer on the second conductive layer;
forming a third conductive layer on the fourth dielectric layer;
removing first portions of the first conductive layer, the third dielectric layer, the second conductive layer, the fourth dielectric layer, and the third conductive layer defining a plurality of capacitive connection structures;
removing second portions of the fourth dielectric layers and the third conductive layers of the plurality of capacitive connection structures to expose regions of the second conductive layers of the plurality of capacitive connection structures;
forming a fifth dielectric layer on the first dielectric layer and on the plurality of capacitive connection structures;
forming a plurality of second interconnection structures extending into and through the fifth dielectric layer to the regions of the second conductive layers of the plurality of capacitive connection structures, each respective second interconnection structure of the plurality of second interconnection structures being in contact with and coupled to a corresponding exposed region of the exposed regions of the second conductive layers of the plurality of capacitive connection structures; and
forming a plurality of third interconnection structures extending into and through the fifth dielectric layer to the third conductive layers of the plurality of capacitive connection structures, each respective third interconnection structure of the plurality of third interconnection structures is coupled to a corresponding third conductive layer of the third conductive layers of the plurality of capacitive connection structures.

16. The method of claim 15, wherein forming the plurality of trenches includes etching the first dielectric layer.

17. The method of claim 15, wherein removing the first portions of the first conductive layer, the third dielectric layer, the fourth dielectric layer, and the third conductive layer defining the plurality of capacitive connection structures includes defining a first pattern with a photoresist process and performing a dry etching to remove the first portions.

18. The method of claim 17, wherein removing the second portions of the fourth dielectric layers and the third conductive layers of the plurality of capacitive connection structures to exposing regions of the second conductive layers of the plurality of capacitive connection structures includes defining a second pattern with a photoresist process and performing a dry etching to remove the second portions.

19. The method of claim 15, further comprising forming a luminous device layer on the fifth dielectric layer and on the plurality of third interconnection structures.

20. The method of claim 19, wherein forming the luminous device layer on the fifth dielectric layer and on the plurality of third interconnection structures further includes forming one or more pixels having a first pitch selected from a range of 2 nanometers (nm) to 100 micrometers (μm), inclusive, and each of the one or more pixels includes three sub-pixels having a second pitch less than the first pitch.
